(19) United States
(12) Patent Application Publication
(10) Pub. No.: US 2024/0347497 A1
(43) Pub. Date: Oct. 17, 2024

(54) THERMAL SOLUTIONS FOR ADVANCED SEMICONDUCTORS

(71) Applicant: International Business Machines Corporation, Armonk, NY (US)

(72) Inventors: SHIDONG LI, Hopewell Junction, NY (US); Kenneth Charles Marston, Poughquag, NY (US); Kalind BARAYA, West Lafayette, IN (US)

(21) Appl. No.: 18/301,367

(22) Filed: Apr. 17, 2023

(51) Int. Cl. H01L 23/00; H01L 23/373; H01L 23/473

(52) U.S. Cl. CPC H01L 24/32; H01L 23/3733; H01L 23/473; H01L 24/29; H01L 24/83; H01L 23/3738; H01L 23/481; H01L 2224/29109; H01L 2224/29147; H01L 2224/29166; H01L 2224/29184; H01L 2224/29186; H01L 2224/2919; H01L 2224/32225; H01L 2224/32235; H01L 2224/32245; H01L 2224/83191; H01L 2224/83894; H01L 2224/83895; H01L 2224/83896; H01L 2924/0544

(57) ABSTRACT

Semiconductor structures are provided with five different cooling elements directly bonded to a semiconductor chip. The cooling element is directly bonded to the backside of a thinned semiconductor substrate or to the front side back-end-of-line (BEOL) interconnect wiring of the semiconductor chip. The cooling element replaces a carrier wafer on semiconductor chips with backside BEOL interconnect wiring. Each of the five cooling elements provide better thermal conductivity for the semiconductor structure when directly bonded to the front side BEOL interconnect wiring than the carrier wafer typically bonded to a semiconductor chip with backside BEOL interconnect wiring. The cooling element is one of a copper cooling element with water-filled microchannels, or a copper plate, a silicon cooling element with water-filled microchannels, a silicon carbide plate, or a glass plate with copper-filled vias. The cooling element is directly bonded to the semiconductor chip by a hybrid bond.

### BACKGROUND

The present invention relates generally to the field of thermal management for semiconductor chips using a backside power delivery network and more particularly to the formation of a semiconductor structure removing heat from the front side of the chip using microchannel cooling elements.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. The integrated circuits in the shrinking semiconductor chips generate heat during operation and as the tighter pitches drive more semiconductor devices into the device area, an increase in the amount of heat generated in the device area occurs. As the temperature of device elements increases, the performance of the semiconductor device is reduced. With decreasing device pitches and more devices present in an area, the challenge to remove the heat generated by the tightly packed devices is increasing. Furthermore, the smaller semiconductor chip sizes provide less surface area for excess heat or thermal energy to escape. In high-speed circuits, the associated semiconductor device power consumption and power generation is large. With increasing device density and the increasing number of high-speed circuits in high-performance semiconductor chips, better heat dissipation methods need to be considered to ensure that the temperature of each semiconductor chip does not exceed the allowable working temperature.

For logic scaling at the two-nanometer node, and beyond, planar and non-planar semiconductor device structures, such as metal-oxide-semiconductor FETs, must be scaled to smaller dimensions. In this regard, Gate All Around (GAA) nanosheet (or nanowire) FET devices are a viable option for continued scaling. GAA nanosheet FET devices have been recognized as excellent candidates to achieve improved power performance and area scaling compared to FinFET technology. GAA nanosheet FET devices can provide high drive currents due to wide effective channel width (Weff) while maintaining short-channel control. However, in many cases, backside power delivery networks are needed to be coupled with GAA nanosheet FETs for performance and back-end-of-line (BEOL) wiring issues.

As the semiconductor industry continues to drive to the two-nanometer technology node with tighter pitches and increasing performance, increased use of backside interconnect layers for a backside power delivery network is emerging. Creating backside interconnect layers below the front-end-of-line semiconductor devices provides improved power performance and more routing options for semiconductor devices relieving some of the BEOL wiring congestion. Utilizing a backside power delivery network can enable ten to thirty-five percent logic area scaling reduction in a two-nanometer technology node that utilizes GAA nanosheet FETs. A backside power delivery network improves semiconductor device gate delay and reduces BEOL wiring congestion.

However, the semiconductor industry's trend to use a backside power distribution network is not without challenges. Providing transistors or front-end-of-line (FEOL) devices that generate heat between the front side BEOL wiring layers and backside BEOL wiring for the backside power delivery network (e.g., a BSPDN) drives additional thermal resistance in the semiconductor chip structure. The FEOL semiconductor devices generating heat now reside between both the front side BEOL interconnect wiring and the backside BEOL interconnect wiring creating the BSPDN. The front side BEOL interconnect wiring layers and the backside BEOL wiring layers provide poor thermal performance. Forming the FEOL semiconductor devices between both the front side BEOL wiring increases the thermal resistance of the path to eliminate FEOL device generated heat and reduces the ability to remove the FEOL semiconductor device generated thermal energy or heat. Additionally, to form the BSPDN, a carrier wafer is attached to the front side BEOL interconnect wiring to allow semiconductor substrate thinning before BSPDN formation. The carrier wafer, typically, composed of silicon is not an effective material for removing thermal energy generated by the semiconductor devices.

### SUMMARY

Embodiments of the present invention disclose five cooling elements that can be directly bonded to either the front side BEOL interconnect wiring of a semiconductor chip or to the backside of a semiconductor chip substrate.

Embodiments of the present invention disclose a semiconductor structure for a semiconductor chip with a front side back-end-of-line (BEOL) interconnect wiring and a cooling element that is one of five cooling elements directly bonded to the front side BEOL interconnect wiring. The cooling element is directly bonded to the front side BEOL interconnect wiring by a hybrid bond to reduce the thermal impedance of the interface between the cooling element and the semiconductor chip. The cooling element directly bonded to the front side BEOL interconnect wiring replaces a carrier wafer in a conventional semiconductor chip formed with backside BEOL interconnect wiring. Replacing the carrier wafer typically composed of a silicon material with a low thermal conductivity with a cooling element such as a copper cooling element or a cooling element with water-filled microchannels directly bonded to the front side BEOL interconnect wiring improves the thermal conductivity of the semiconductor structure compared to the conventional semiconductor structure of a semiconductor chip with backside BEOL interconnect wiring and a silicon carrier wafer. Improving the thermal conductivity of the semiconductor chip improves the semiconductor device electrical performance and may allow more semiconductor devices in the semiconductor chip.

Embodiments of the present invention disclose a semiconductor structure for a semiconductor chip with a front side back-end-of-line (BEOL) interconnect wiring, a backside BEOL interconnect wiring, and one or more through-silicon vias. The semiconductor structure includes a metal cooling element directly bonded to the front side BEOL interconnect wiring. The metal cooling element is one of a copper plate or a copper cooling element with a plurality of water-filled microchannels. The copper cooling element is directly attached to the front side BEOL interconnect wiring by one of a copper hybrid bond, an oxide hybrid bond, or an oxide-copper hybrid bond. The copper cooling clement replaces a silicon carrier wafer on a conventional semiconductor chip with the backside BEOL interconnect wiring. Each of the metal cooling elements have a higher thermal conductivity than the silicon carrier wafer. Replacing the silicon carrier wafer with one of the metal cooling elements with a higher thermal conductivity removes more semiconductor device generated thermal energy. Removing more thermal energy improves the electrical performance of the semiconductor devices in the semiconductor chip and may allow more semiconductor devices in the semiconductor chip.

Embodiments of the present invention disclose a semiconductor structure for a semiconductor chip with a thinned semiconductor substrate and a semiconductor cooling element directly bonded to the backside of the thinned semiconductor substrate. The semiconductor cooling element is one of a silicon-based cooling element with a plurality of microchannels filled with circulating chilled water or a silicon carbide plate. The semiconductor cooling element is directly bonded to the backside of the thinned semiconductor substrate by a hybrid bond using one of a copper hybrid bond, an oxide hybrid bond, or a combination of an oxide and copper hybrid bond. Directly bonding the backside of the thinned semiconductor substrate to the semiconductor cooling element with a higher thermal conductivity than the silicon semiconductor substrate of the semiconductor chip improves the thermal conductivity of the semiconductor structure and thereby improving the electrical performance of the semiconductor devices in the semiconductor chip.

Embodiments of the present invention disclose a semiconductor structure for a semiconductor chip with a thinned semiconductor substrate and a metal cooling element directly bonded to a backside of the thinned semiconductor substrate. The metal cooling element can be one of a copper plate or a copper cooling clement with a plurality of microchannels. The microchannels are filled with circulating, chilled water. The metal cooling elements are directly bonded to the backside of the thinned semiconductor substrate by a hybrid bond between the metal cooling element and the backside of the thinned semiconductor substrate. The hybrid bond may be formed using one of a copper hybrid bond, an oxide hybrid bond, or a combination of an oxide and copper hybrid bond. Thinning the semiconductor substrate and directly attaching a metal cooling clement improves the thermal conductivity of the semiconductor structure and improves the electrical performance of the semiconductor devices in the semiconductor chip. Improving the thermal conductivity of the semiconductor structure may allow more semiconductor devices in the semiconductor chip.

Embodiments of the present invention provide a method of forming a semiconductor structure with a semiconductor chip with through-silicon vias attaching by a bonding layer to a cooling element. The semiconductor chip has a bond layer deposited on the front side BEOL interconnect wiring. The cooling element can be any one of a copper plate, a copper cooling element with water-filled microchannels, a silicon cooling element with water-filled microchannels, a silicon carbide plate, or a glass cooling element with copper-filled vias. Curing the bond layer occurs using a hybrid bonding process. The direct bonding of the cooling element to the semiconductor chip reduces the thermal impedance of the thermal interface between the semiconductor chip and the cooling element thereby improving the thermal conductivity of the semiconductor structure compared to a conventional semiconductor structure with the silicon carrier wafer. The method includes flipping the semiconductor substrate over and thinning the backside of the semiconductor substrate to form backside BEOL interconnect wiring and interconnects on the semiconductor substrate.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a cross-sectional view of a semiconductor structure with a backside power delivery network on a thinned semiconductor substrate and a cooling element attached to the back-end-of-line (BEOL) interconnect wiring layers of the semiconductor chip, in accordance with an embodiment of the present invention.

FIG. 2 depicts a cross-sectional view of the semiconductor structure after forming through-silicon vias (TSVs) on a landing pad on a semiconductor substrate, in accordance with an embodiment of the present invention.

FIG. 3 depicts a cross-sectional view of the semiconductor structure after forming front-end-of-line (FEOL) devices on the semiconductor substrate, forming middle-of-line (MOL) layers on the FEOL devices, and forming back-end-of-line (BEOL) interconnect layers on the MOL layers, in accordance with an embodiment of the present invention.

FIG. 4 depicts a cross-sectional view of the semiconductor structure after applying a bonding layer on the top surface of the BEOL wiring, in accordance with an embodiment of the present invention.

FIG. 5 depicts a cross-sectional view of the semiconductor structure after attaching a cooling element and curing the bonding layer to attach the cooling element to the BEOL wiring, in accordance with an embodiment of the present invention.

FIG. 6 depicts a cross-sectional view of the semiconductor structure after flipping the semiconductor structure to thin the semiconductor substrate, in accordance with an embodiment of the present invention.

FIG. 7 depicts a cross-sectional view of the semiconductor structure after forming a backside power delivery network (BSPDN) using the backside BEOL wiring on exposed surfaces of the thinned semiconductor substrate and the TSVs, in accordance with an embodiment of the present invention.

FIG. 8 depicts a cross-sectional view of the semiconductor structure after forming chip interconnections on the backside BEOL wiring, in accordance with an embodiment of the present invention.

FIG. 9 depicts a cross-sectional view of an example of a copper plate for the cooling element, in accordance with an embodiment of the present invention.

FIG. 10 depicts a cross-sectional view of an example of a semiconductor cooling element composed of silicon carbide plate, in accordance with an embodiment of the present invention.

FIG. 11 depicts a cross-sectional view of an example of the semiconductor cooling element with a silicon microchannel structure, in accordance with an embodiment of the present invention.

FIG. 12 depicts a cross-sectional view of an example of a copper cooling element with a copper microchannel structure, in accordance with an embodiment of the present invention.

FIG. 13 depicts a cross-sectional view of an example of a glass cooling element with copper-filled vias, in accordance with an embodiment of the present invention.

FIG. 14 is a flow chart depicting a first example of operational steps to form a semiconductor chip with cooling element attached to the front side BEOL interconnect wiring, in accordance with an embodiment of the present invention.

FIG. 15 is a flow chart depicting a second example of operational steps to form a semiconductor chip with cooling element attached to a backside of a semiconductor chip substrate, in accordance with an embodiment of the present invention.

FIG. 16 depicts a cross-sectional view of a semiconductor chip a cooling element bonded to the backside of the semiconductor substrate, in accordance with an embodiment of the present invention.

### DETAILED DESCRIPTION

Embodiments of the present invention recognize that increasing system performance requirements continue to drive tighter pitches in semiconductor devices and smaller semiconductor chips. Additionally, some high-performance applications may require high-speed circuits consuming and generating large amounts of power. During operation, semiconductor devices generate thermal energy and as the number of semiconductor devices in a fixed area increases, the amount of thermal energy generated in that area increases. As the temperature of the semiconductor device elements increases, the performance of the semiconductor device is reduced. Therefore, developing methods to remove thermal energy from the semiconductor devices in order to maintain semiconductor device performance is needed, especially, as smaller semiconductor chips with less surface area to eliminate thermal energy and semiconductor chips with more devices continue to emerge.

Embodiments of the present invention recognize that creating backside back-end-of-line (BEOL) interconnect layers for a backside power delivery network (BSPDN) below the front-end-of-line (FEOL) semiconductor devices offers semiconductor device performance advantages and more routing options for semiconductor devices. This is especially true for densely packed three-dimensional semiconductor devices such as gate-all-around (GAA) nanosheet field-effect transistor (FET) devices needed for the two-nanometer technology node to attain both device area reduction and performance improvements for high drive currents with short-channel control. Providing a backside power delivery network in the backside BEOL interconnect layers also improves the gate delay while reducing the BEOL wiring congestion. Utilizing a backside power delivery network can enable ten to thirty-five percent logic area scaling in the two-nanometer technology node.

Embodiments of the present invention recognize that forming both the backside BEOL interconnect wiring layers for a backside power delivery network (BSPDN) and the front side BEOL wiring around the FEOL semiconductor devices increases the thermal resistance in the device path used to eliminate device generated heat and reduce the device temperature. For example, the thermal conductivity of BEOL wiring has been modeled and estimated to be in the range of 3 W/m deg. K (e.g., a low thermal conductivity). Furthermore, advanced semiconductor chips using backside BEOL wiring are typically formed with a carrier wafer attached to the front side BEOL wiring to perform semiconductor wafer thinning before forming the BSPDN. Embodiments of the present invention recognize that a conventional carrier wafer is composed of a semiconductor material such as silicon that does not provide good thermal conductivity. Embodiments of the present invention recognize that in semiconductor chips formed with both backside and front BEOL interconnect wiring layers, a method to improve the thermal path to remove the semiconductor device generated thermal energy desirable.

Furthermore, embodiments of the present invention recognize that a mismatch of the coefficients of thermal expansion (CTE) between the back-end-of-line (BEOL) layers and a directly attached cooling element is generally believed to cause excessive thermomechanical stresses. Additionally, the use of conventional thermal interface materials such as an adhesive layer with a thicker bond line to attach a conventional carrier wafer causes a thermal resistance penalty compared to directly attaching a cooling element by hybrid bonding to the semiconductor chip.

Embodiments of the present invention provide a number of semiconductor structures for a semiconductor chip with one of five cooling elements directly bonded to either the backside of a semiconductor substrate or to the front side BEOL wiring of a semiconductor chip. The cooling element is directly bonded to the semiconductor chip using a hybrid bonding process.

Five different cooling elements are disclosed. Each of the five cooling elements can attach directly to either the BEOL wiring or to the backside of a thinned semiconductor substrate in embodiments of the present invention. In embodiments of the present invention disclosing a cooling element directly attached to the front side BEOL interconnect wiring, the cooling clement replaces the silicon carrier wafer typically used to form the backside BEOL wiring. The silicon carrier wafer has a low thermal conductivity. Replacing the silicon carrier wafer with the cooling elements with a higher thermal conductivity can improve semiconductor chip performance and may allow more semiconductor devices in the semiconductor chip.

The five cooling elements, disclosed in the embodiments of the present invention, allow the selection of the cooling element to be directly joined to the semiconductor chip that maximizes the thermal performance of the semiconductor chip and minimizes CTE mismatch between the semiconductor chip and the selected cooling element. Minimizing the CTE mismatch allows direct bonding of the cooling element to the semiconductor chip using a hybrid bonding process while maximizing the thermal performance of the semiconductor structure includes reduces the thermal impedance to increase the thermal energy dissipated by the cooling element attached to the semiconductor chip.

Embodiments of the present invention provide cooling elements formed with different materials (e.g., a metal material, a semiconductor material, and a glass material with copper-filled vias) with different structures such as plates, plates with water-filled microchannels, and plates with copper-filled vias that can be joined by hybrid bonding to either a surface of the BEOL interconnect wiring or the backside of a thinned semiconductor substrate. Embodiments of the present invention provide a thermal engineer, chip designer, or system designer with various cooling elements that can be selected for direct attachment by hybrid bonding to a semiconductor chip to meet the thermal requirements of a semiconductor chip while also providing a similar CTE to meet the mechanical requirements of the bond layer to directly join the cooling element, for example by hybrid bonding, to the semiconductor chip.

Thermal modeling of a conventional semiconductor structure with a BSPDN that is formed using a conventional silicon carrier wafer bonded to the BEOL wiring estimated the thermal impedance generated by the silicon carrier wafer accounts for about 75% of the thermal impedance or thermal resistance in the semiconductor structure (modelled from the FEOL semiconductor devices to the top surface of the silicon carrier wafer). Embodiments of the present invention replacing the silicon carrier wafer with a cooling element, such as a copper plate that has a much higher thermal conductivity than silicon carrier wafer, greatly improves the ability to remove thermal energy from the semiconductor structure. As the industry continues to move toward denser and smaller, high-performance semiconductor chips, the ability to remove more thermal energy from the semiconductor chip using the semiconductor structures with the cooling elements disclosed in the present invention will be increasingly important.

Embodiments of the present invention provide cooling elements with microchannels that can be filled with chilled, circulating water. The cooling elements using water-filled microchannels can remove the thermal energy from the semiconductor chip more efficiently than the conventional silicon carrier wafer bonded to the front side BEOL wiring. Thermal modeling has predicted that hot spot cooling is significantly improved (e.g., 25-30 degrees Celsius lower maximum hot spot temperature) with a copper-based microchannel cooling element directly attached to BEOL wiring by hybrid bonding compared to a semiconductor device with a carrier wafer attached to the BEOL wiring using conventional carrier wafer bonding and a silicon carrier wafer. The thermal model predicted improved hot spot cooling (e.g., 7-10 degrees Celsius lower maximum hot spot temperature) with the silicon-based microchannel cooling element attached to BEOL wiring compared to a semiconductor device with the silicon carrier wafer attached to the BEOL wiring. Embodiments of the present invention provide semiconductor structures with cooling elements bonded to the front side BEOL wiring that improve the thermal performance of semiconductor chips with backside BEOL wiring and a thinned wafer substrate. Embodiments of the present invention replace the conventional carrier wafer with one of five cooling elements directly bonded to the front side BEOL wiring of a semiconductor chip with backside BEOL wiring.

Additionally, modeling of the thermal coefficient of expansion (CTE) of the BEOL wiring determined that the BEOL CTE is much closer to the CTE of a copper-based cooling element than to the CTE of a silicon carrier wafer. The similar CTEs of the BEOL wiring and the copper-based cooling elements allows direct bonding of the copper-based cooling elements to the BEOL wiring by hybrid bonding. Embodiments of the present invention provide direct bonding of one of a metal material cooling element, a semiconductor-material based cooling element, or a glass-based cooling element to the semiconductor chip by one of oxide hybrid bonding creating an oxide hybrid bond, copper hybrid bonding creating a copper hybrid bond, or oxide-copper bonding creating an oxide-copper bond. The direct bonding of the cooling elements to the semiconductor chip reduces the thermal impedance of the semiconductor structure. Hybrid bonding is known as a direct bond interconnect. Direct bonding of the cooling elements by hybrid bonding improves the removal of the FEOL device generated thermal energy.

The five types of cooling elements are disclosed in embodiments of the present invention that can replace the conventional silicon carrier wafer typically attached to a semiconductor chip with a BSPDN. Additionally, embodiments of the present invention also provide semiconductor structures with one of the five types of cooling elements bonded to the backside of a thinned semiconductor substrate to improve the thermal performance of semiconductor chips without backside BEOL interconnect wiring.

The five types of cooling elements of embodiments of the present invention include (1) a copper plate, (2) a silicon carbide plate, (3) a silicon microchannel element that uses forced, chilled water circulating in the microchannels, (4) a copper microchannel element that uses forced, chilled water in the microchannels, and (5) a glass plate or element with copper-filled vias. For example, embodiments of the present invention attaching a cooling element composed of copper or silicon using circulating chilled water-filled microchannels improve the ability of the cooling element to remove the semiconductor device generated thermal energy compared to a silicon carrier wafer attached to a semiconductor chip with a backside power delivery network (BSPDN). Similarly, embodiments of the present invention attaching cooling elements or plates composed of a metal (e.g., copper), silicon carbide, or glass with copper-filled vias can provide better cooling capability than a typical silicon carrier wafer attached to the semiconductor chip due to the higher thermal conductivity of the metal such as copper and silicon carbide. Additionally, the five types of cooling elements disclosed in embodiments of the present invention can be directly attached by hybrid bonding to a backside of a semiconductor chip without backside BEOL wiring.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration purposes only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating, or semiconductor layers at the interface of the two elements.

In the interest of not obscuring the presentation of embodiments of the present invention, in the following detailed description, some processing steps or operations that are known in the art may have been combined for presentation and illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so many of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. The present embodiments may use the terms device structure and semiconductor structure interchangeably. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure, or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

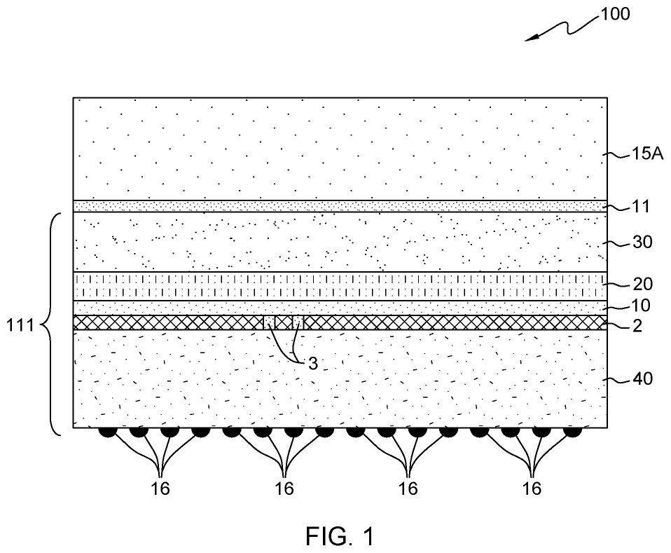

FIG. 1 depicts a cross-sectional view of semiconductor structure 100 with cooling clement 15A attached to semiconductor chip 111, in accordance with an embodiment of the present invention. As depicted, FIG. 1 includes semiconductor chip 111 with interconnects 16, backside BEOL wiring 40, substrate 2, FEOL devices 10, MOL layers 20, front side BEOL wiring 30, bonding layer 11, and cooling element 15A attached by bonding layer 11 to front side BEOL wiring 30. Semiconductor chip 111 can be any type of semiconductor chip (e.g., logic chip or memory chip) formed with known semiconductor processes and materials. In one embodiment, cooling element 15A is attached to more than one semiconductor chip 111.

Substrate 2 is a thinned semiconductor substrate or thinned portion of a wafer. Substrate 2 can be composed of any semiconductor chip substrate material. In various embodiments, substrate 2 is composed of silicon. In other embodiments, substrate 2 is composed of a group IV semiconductor material, a group II-VI semiconductor material, or a group IV semiconductor material. For example, substrate 2 may be composed of but not limited to SiC, SiGe, GaAs, or InAs, ZnTe, CdTe, ZnCdTe, GaAlAs, InGaAs, InAlAs, InAlAsSb, InAlAsP, and InGaAsP. In various embodiments, substrate 2 is a wafer or a portion of a wafer. In some embodiments, substrate 2 is one of doped, undoped, or contains doped regions, undoped regions, or defect rich regions. In an embodiment, substrate 2 is one of a layered semiconductor substrate, such as a semiconductor-on-insulator substrate (SOI), Ge on insulator (GeOI) or silicon-on-replacement insulator (SRI).

In various embodiments, through-silicon vias (TSVs) 3 are included in substrate 2 connecting FEOL devices 10 to backside BEOL wiring 40. In some cases, the TSVs can be nano TSVs in thinned semiconductor wafer.

As depicted in FIG. 1, FEOL devices 10 are formed on substrate 2. The specific semiconductor devices formed in FEOL devices 10 include, but are not limited to, logic devices including field-effect transistors (FET), finFETs, gate-all-around (GAA) nanosheet FETs, complimentary-metal-oxide-semiconductors (CMOS devices), and other FEOL devices that can be formed with known semiconductor processes. Each semiconductor device formed in FEOL devices 10 is not specifically depicted in FIG. 1. Typically, the FEOL devices 10 may be formed in the MO metal layer of the semiconductor chip and typically connect to the MOL contacts, wiring, and devices in MOL layers 20.

MOL layers 20 can be formed above FEOL devices 10 using known semiconductor processes. As known to one skilled in the art, MOL layers 20 includes typically includes at least one layer or several layers of contacts and connections to the FEOL devices 10 but may also include some semiconductor devices such as memory devices, passive devices, FET structures (not specifically depicted in FIG. 1) that are surround by one or more layers of dielectric materials (not specifically depicted in FIG. 1).

Front side BEOL wiring 30 can be formed on MOL layers 20 using known semiconductor processes. As known to one skilled in the art, front side BEOL wiring 30 can be a front side BEOL interconnect wiring structure that includes many layers of interconnect wiring. vias, contacts, passive devices, power delivery structures, and layers of interlayer dielectric (ILD) that not specifically depicted in FIG. 1.

Bonding layer 11 can be composed of an oxide-based material, a copper material, or any suitable polymer or adhesive material for joining cooling element 15A to front side BEOL wiring 30. In a thermal model of a conventional semiconductor structure, the oxide-based carrier wafer bond layer was modeled to be approximately 6% of the thermal impedance of a semiconductor structure with a thinned semiconductor substrate, a BSPDN, and a silicon carrier wafer. In various embodiments, bonding layer 11 forms a direct bond with the semiconductor chip using is an oxide-based hybrid bond. The hybrid bond or direct bonding of cooling element 15A to semiconductor chip 111 reduces the thermal impedance (e.g., very thin to no thermal interface thickness). In other embodiments, bonding layer 11 provides hybrid copper bonding of cooling element 15A to front side BEOL wiring 30 which provides even a smaller thermal resistance or thermal impedance that the thermal impedance of an oxide-based hybrid bond. As known to one skilled in the art, hybrid bonds are a known as a direct interconnect bonds. As previously discussed, in various embodiments, any one of cooling element 15B, 15C, 15D, or 15E can replace cooling element 15A on semiconductor chip 111.

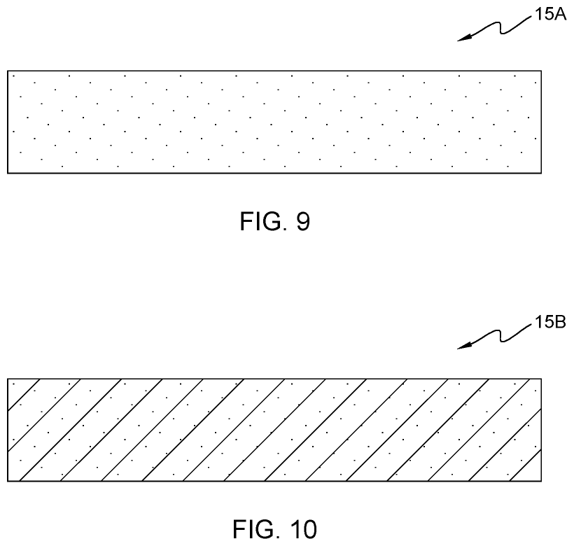

As known to one skilled in the art, hybrid copper bonding is a permanent bond that combines a dielectric bond (SiOx) with embedded metal (e.g., copper) to form interconnections. In SiOx, x can be an integer greater than 0. In some embodiments, bonding layer 11 is formed with one of indium (In), tungsten (W), copper (Cu), or titanium (Ti) and a dielectric bond (e.g., SiOx). In some cases, a layer of copper may be deposited over the oxide layer to from bonding layer 11 (e.g., copper-copper bond). Bonding layer 11 is not limited to these materials and may be formed using other bonding elements. For example, a polymer material may be used to bond cooling element 15A or any of cooling elements 15B, 15C. 15D, or 15E to semiconductor chip 111. Bonding layer 11 can be determined, as least in part, by the type of materials in the cooling element such as cooling element 15A, cooling element 15B, cooling element 15C, cooling element 15D, or cooling element 15E that are discussed in detail later with respect to FIGS. 9-13. In some embodiments, bonding layer 11 can be applied by spin-coating, atomic layer deposition (ALD), chemical vapor deposition (CVD), or other thin film deposition process used with oxide or adhesive materials.

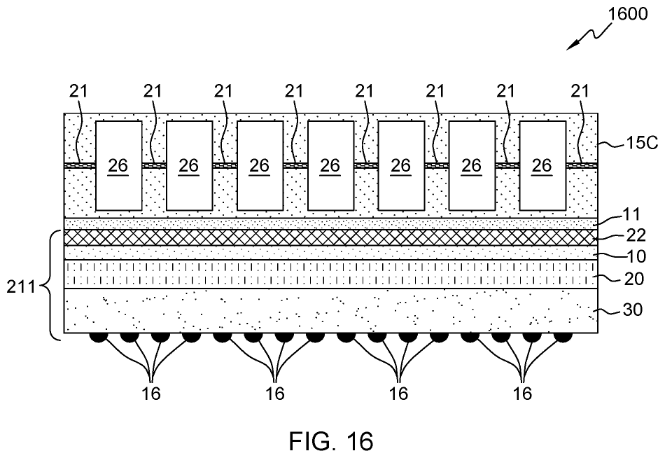

In various embodiments, bonding layer 11 is a thin coat of an oxide-based material for hybrid bonding. A hybrid bonding processes can be a method of direct bonding of two elements, two semiconductor wafers or portions of semiconductor wafer substrates, or a portion of a wafer substrate to another element, generally using a curing or heating process. For example, hybrid bonding can include bonding an oxide-to-oxide surface, copper-to-copper surface, or oxide-to-metal surface to join the cooling element (e.g., cooling element 15A depicted in FIG. 1) to the semiconductor chip (e.g., semiconductor chip 111 depicted in FIG. 1 or semiconductor chip 211 depicted in FIG. 16). As depicted in FIG. 1, bonding layer 11 may be a silicon oxide bonding layer deposited on front side BEOL wiring 30. The bonding layer 11, after curing, attaches cooling element 15A (e.g., a copper plate) to front side BEOL wiring 30 in semiconductor chip 111. In some cases, the surface of cooling element 15A is pre-oxidated. In other cases, a thin layer of an oxide or a polymer material is deposited on a surface of cooling element 15A to be bonded to bonding layer 11. In various embodiments, a hybrid copper bonding process using bonding layer 11 attaches cooling element 15A to front side BEOL wiring 30. In other embodiments, any one of cooling elements 15B, 15C, 15D, or 15E are directly bonded to front side BEOL wiring 30 instead of cooling element 15A using a hybrid bonding process.

Cooling element 15A is one example of a cooling element replacing a semiconductor carrier or handling wafer on a semiconductor chip formed with backside BEOL interconnect wiring. In other examples, any one of cooling element 15B, 15C, 15D, or 15E may replace the carrier wafer. As known to one skilled in the art, a carrier wafer is typically attached to the front side BEOL interconnect wiring of a semiconductor substrate prior to backside wafer thinning or grinding. However, in various embodiments of the present invention, a cooling clement, such as cooling element 15A is attached to front side BEOL wiring 30 instead of the silicon carrier wafer. Backside BEOL interconnect wiring 40 is formed on the thinned backside of substrate 2.

As depicted in FIG. 1, instead of attaching a conventional silicon carrier wafer to front side BEOL wiring 30 prior to wafer thinning, cooling element 15A is attached to front side BEOL wiring 30. In various embodiments, cooling element 15A is a copper plate or a portion of a copper plate. As depicted in FIG. 1, cooling element 15A is attached or bonded to the top surface of front side BEOL wiring 30 by bonding layer 11.

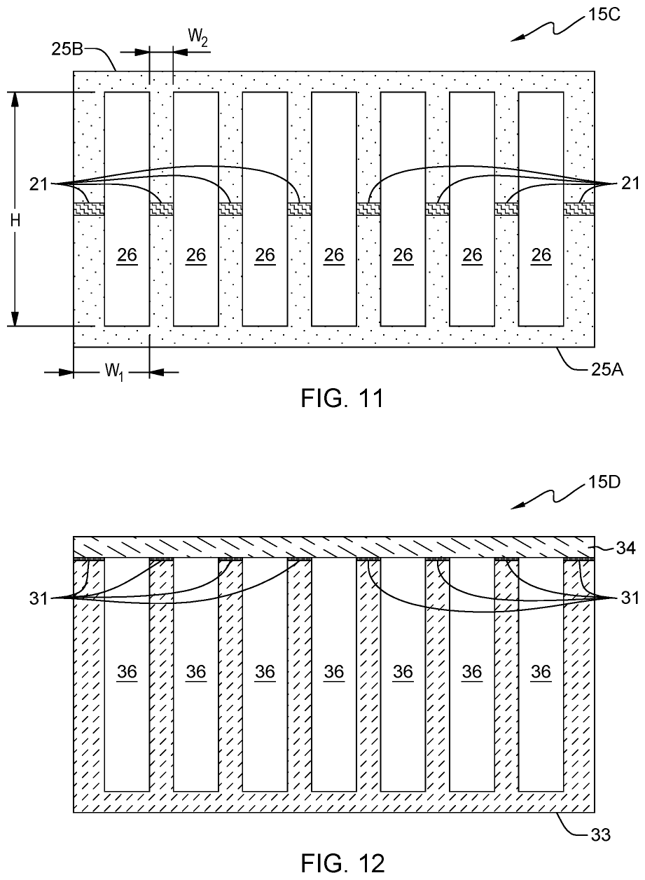

As previously discussed, modeling of the CTE of the layers of the various conductive and dielectric materials composing front side BEOL wiring 30 have a CTE in the range of 10 to 14 ppm/C (part per million/deg. C). The modeled BEOL CTE is much closer to the CTE of copper (CTE of copper is approximately 16 ppm/C) than the CTE of silicon (CTE of silicon is approximately 2.5 ppm/C). The small CTE mismatch between the copper used in cooling element 15A and the modeled CTE of front side BEOL wiring 30 allows direct bonding of cooling element 15A to front side BEOL wiring 30. Similarly, cooling element 15D, depicted later in FIG. 11, composed of copper with water-filled microchannels also has a similar CTE to front side BEOL wiring 30.

In other embodiments, a different cooling element is attached to front side BEOL wiring 30 using bonding layer 11 which may be composed of different materials for the bonding process. As depicted later in FIGS. 9-13, cooling elements 15A, 15B, 15C, 15D, and 15E illustrate different types of cooling elements and materials that can be substituted in place of cooling element 15A on semiconductor chip 111. Each of cooling element 15A, 15B, 15C, 15D, and 15E, when directly bonded by bonding layer 11 to front side BEOL wiring 30, can remove heat generated by the devices in semiconductor chip 111 better than a silicon carrier wafer. The thermal conductivity of each of cooling element 15A, 15B, 15C, 15D, and 15E attached to front side BEOL wiring 30 of semiconductor chip 111 by bonding layer 11 is higher or better than the thermal conductivity of a conventional silicon carrier wafer (not depicted) bonded to semiconductor chip 111. In some cases, discussed later, cooling elements 15C, 15D and 15E use microchannels with circulating cold water to attain improved thermal conductivity compared to the thermal conductivity of a conventional silicon carrier wafer.

Backside BEOL wiring 40 is under substrate 2 in FIG. 1. Backside BEOL wiring 40 can be formed on the exposed backside surface of substrate 2 and TSVs 3 after thinning substrate 2. Formed using known BEOL semiconductor processes, backside BEOL wiring 40 can be a BSPDN. Backside BEOL wiring 40 can be used to relieve MOL and BEOL wiring congestion and improve power delivery from interconnects 16 to the FEOL devices 10. As previously discussed, the addition of backside BEOL wiring 40 with multiple layers of dielectric materials also reduces the ability of the FEOL device generated heat to be removed. For example, the thermal conductivity of backside BEOL wiring 40 has been modeled and estimated to be in the range of 3 W/m deg. K (e.g., a low thermal conductivity). However, as previously discussed, modeling of the CTE of the layers of the various conductive and dielectric materials composing BEOL wiring generates a CTE much closer to copper (CTE of approximately 16 ppm/C) than silicon (CTE of approximately 2.5 ppm/C).

As depicted in FIG. 1, interconnects 16 are on under backside BEOL wiring 40. Typically, interconnects 16 will connect semiconductor chip 111 to a package substrate (not depicted) under semiconductor chip 111. Interconnects 16 can be any kind of semiconductor chip connection to a semiconductor package or, a next level package. In some embodiments, interconnects 16 can connect semiconductor chip 111 to another semiconductor chip. Interconnects 16 on semiconductor chip 111 can be, but are not limited to, solder balls, solder bumps, copper pillars, metal pads, or metal bumps.

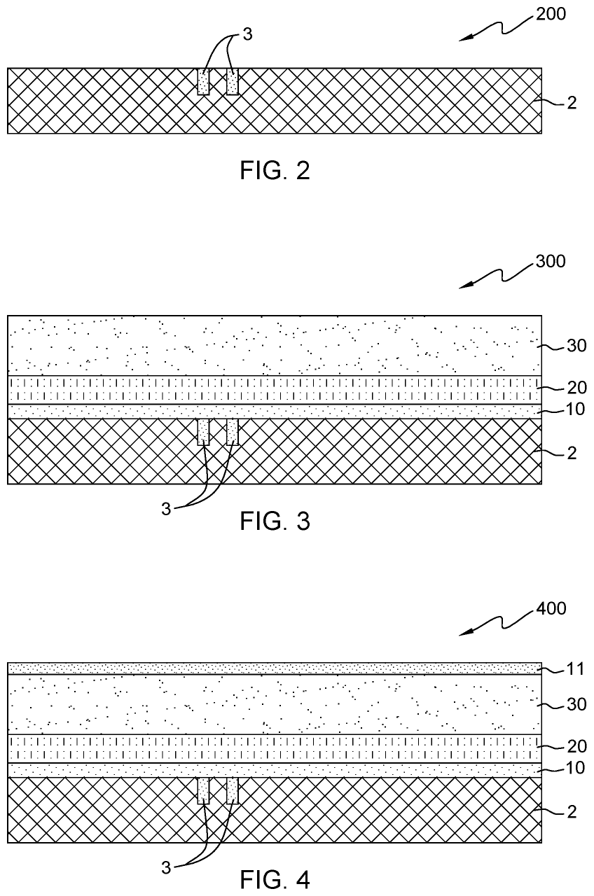

FIG. 2 depicts a cross-sectional view of the semiconductor structure 200 after forming blind vias for TSVs 3 in substrate 2, in accordance with an embodiment of the present invention. As depicted, FIG. 2 includes substrate 2 and two blind vias for TSVs 3.

As discussed in detail with respect to FIG. 1, substrate 2 can be a semiconductor substrate, wafer, or portion of a wafer. Using known TSV formation methods (e.g., reactive ion via etch, liner deposition, or via fill) TSVs 3 can be formed. As depicted in FIG. 2, TSVs 3 are formed using blind vias. In some embodiments, TSVs 3 are through silicon vias (not depicted in FIG. 1) that are etched from the top surface of substrate 2 to the bottom surface of substrate 2. In some embodiments, TSVs 3 are nano TSVs. Nano TSVs have a very small diameter, for example in the range of but not limited to 100 um or less.

FIG. 3 depicts a cross-sectional view of semiconductor structure 300 after forming FEOL devices 10 on semiconductor substrate 2 with TSVs 3, forming MOL layers 20 on the FEOL devices 10, and forming front side BEOL wiring 30 on the MOL layers 20, in accordance with an embodiment of the present invention. As depicted, FIG. 3 includes substrate 2, TSVs 3, FEOL devices 10, MOL layers 20, and front side BEOL wiring 30. FEOL devices 10, MOL layers 20, and front side BEOL wiring 30 are formed with known semiconductor processes.

FIG. 4 depicts a cross-sectional view of semiconductor structure 400 after applying a bonding layer 11 on the top surface of the front side BEOL wiring 30, in accordance with an embodiment of the present invention. As depicted, FIG. 4 includes the elements of FIG. 3 and bonding layer 11.

As previously discussed in detail with regard to FIG. 1, bonding layer 11 may be deposited on the top surface of BEOL interconnect wiring 30 by spin coating, deposited by atomic layer deposition or another known deposition process. A planarization process such as chemical mechanical polish may be performed on as deposited bonding layer 11. Bonding layer 11 may be composed of but not limited to dielectric bond materials, for example, SiO₂ and at least one of Cu, Ti, W, or In but is not limited these materials. Bonding layer 11, for example, can be cured later to attach one of the cooling elements discussed in detail later with respect to FIGS. 9-13 to front side BEOL wiring 30.

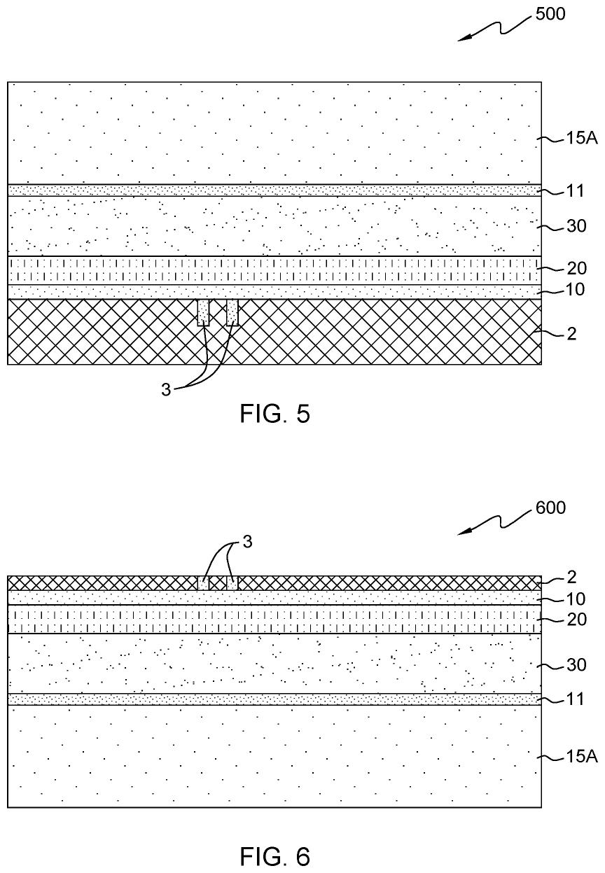

FIG. 5 depicts a cross-sectional view of semiconductor structure 500 after attaching the cooling element 15A and curing bonding layer 11, in accordance with an embodiment of the present invention. As depicted, FIG. 5 includes the elements of FIG. 4 with cooling element 15A bonded to the top surface of front side BEOL wiring 30.

For example, using an automated semiconductor placement tool, cooling element 15A is placed on bonding layer 11. Using a known hybrid copper bonding process, for example, bonding layer 11 can be cured to attach cooling element 15A to front side BEOL wiring 30.

FIG. 6 depicts a cross-sectional view of semiconductor structure 600 after flipping the semiconductor structure to thin the backside of substrate 2, in accordance with an embodiment of the present invention. As depicted, FIG. 6 includes the elements of FIG. 5 without the top portions of substrate 2 and TSVs 3 after wafer flipping.

As depicted in FIG. 6, semiconductor structure 500 is flipped to expose the surface of substrate 2 as the top surface of semiconductor structure 600. After flipping, substrate 2 is thinned, for example, using known backside wafer grinding and/or wet etching processes. After thinning substrate 2, a portion of each TSVs 3 is exposed. As depicted in FIG. 6, the top surface of semiconductor structure 600 includes a portion of the two TSVs 3 and the top surface of the thinned substrate 2.

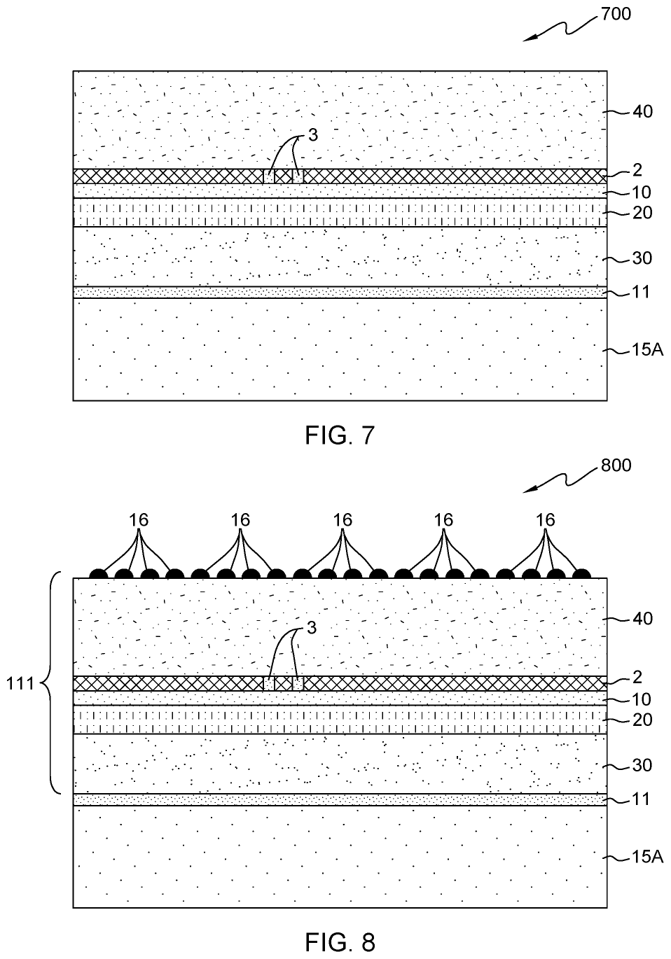

FIG. 7 depicts a cross-sectional view of semiconductor structure 700 after forming backside BEOL wiring 40 on the exposed surfaces of substrate 2 and TSVs 3, in accordance with an embodiment of the present invention. As depicted, FIG. 7 includes the elements of FIG. 6 with backside BEOL wiring 40.

In various embodiments, backside BEOL wiring 40 is a backside power delivery network (BSPDN). Backside BEOL wiring 40 is formed using known BEOL semiconductor processes and may be composed of multiple layers of wiring, power distribution structures, and vias in one or more layers of dielectric material. As known to one skilled in the art, backside BEOL wiring 40 formed on the thinned substrate 2 and TSVs 3 can provide a power distribution network to FEOL devices 10 improving device electrical performance and/or provides additional wiring for device interconnections to relieve wiring congestion in MOL layers 20 and front side BEOL wiring 30.

FIG. 8 depicts a cross-sectional view of semiconductor structure 800 after forming interconnections 16 on the backside BEOL wiring 40, in accordance with an embodiment of the present invention. As depicted, FIG. 8 includes the elements of FIG. 7 and interconnects 16. Semiconductor chip 111 composed of backside BEOL wiring 40, interconnects 16, substrate 2, FEOL devices 10, MOL layers 20, front side BEOL wiring 30, bonding layer 11, and cooling element 15A is identified and labeled in FIG. 8.

As previously discussed, interconnects 16 can be formed on backside BEOL wiring 40. Interconnects 16 can be for any type of semiconductor chip connection to another level of semiconductor packaging such as a module substrate, a printed circuit board, or another semiconductor substrate. As depicted in FIG. 8, interconnects 16 are solder bumps. In other examples, interconnects 16 can be but are not limited to solder balls, copper pillars joined by solder to backside BEOL wiring 40, metal pads, etc.

FIG. 9 depicts a cross-sectional view of cooling clement 15A, in accordance with an embodiment of the present invention. In various embodiments, cooling element 15A is a copper plate with a width and length that is essentially the same size (i.e., the same width and length) of the semiconductor chip cooling element 15A is to be attached to. In other embodiments, cooling element 15A is composed of a different metal material (e.g., aluminum with an aluminum oxide surface). As depicted in FIG. 1 and FIG. 8, cooling element 15A has the same width and length as semiconductor chip 111. The thickness of cooling element 15A can be in the range of 200 to 800 um but is not limited to these thicknesses (e.g., 15A may be thicker or thinner than this range).

Cooling element 15A composed of copper provides a thermal conductivity in the range of 385 W/M deg. K. In various embodiments, cooling element 15A can be joined to a semiconductor chip instead of bonding a silicon carrier wafer to the semiconductor chip. For example, the thermal conductivity of cooling element 15A when joined to front side BEOL wiring 30 of semiconductor chip 111 in FIG. 1, provides a higher thermal conductivity than the thermal conductivity of a typical silicon carrier wafer. The thermal conductivity of a silicon carrier wafer is in the range of 130 W/m deg. K. In this way, bonding cooling element 15A to semiconductor chip 111 in the place of a conventional silicon carrier wafer removes more heat or thermal energy from semiconductor chip 111 than a silicon carrier wafer bonded to semiconductor chip 111 would. Replacing a conventional silicon carrier wafer with cooling element 15A on a high-performance chip with a thinned semiconductor substrate and backside BEOL wiring for a BSPDN allows more heat to be removed from the semiconductor chip. As previously discussed, removing excess heat from the semiconductor chip improves the semiconductor chip's performance. In some cases, the ability to remove more heat from the semiconductor device may allow more semiconductor devices to be formed in the semiconductor chip (i.e., more devices improving the semiconductor chip functionality and/or performance).

Furthermore, cooling element 15A composed of copper has a coefficient of thermal expansion in the range of 16-17 ppm/C which is closer to the coefficient of thermal expansion (CTE) of the BEOL wiring which can be modeled in the range of 10 to 14 ppm/deg. C than a conventional silicon carrier wafer (e.g., CTE of silicon is approximately 2.6 ppm/C). As depicted in FIG. 1, attaching cooling element 15A creates less mechanical stress in bonding layer 11 and to semiconductor chip 111 than attaching a conventional silicon carrier wafer with much lower coefficient of thermal expansion. The CTE of cooling element 15A, matches, within a threshold (e.g., 10-30%), the CTE of the backside BEOL interconnect wiring.

Replacing a silicon carrier wafer with cooling element 15A both improves the thermal conductivity of the material to be attached to the semiconductor chip and reduces the mechanical stresses induced by cooling element 15A compared to a conventional silicon carrier wafer. The conventional silicon carrier wafer with a significantly lower CTE than either front side BEOL wiring 30 or cooling element 15A will create larger mechanical stresses on the semiconductor chip and the bonding layer (e.g., bonding layer 11). In some cases, more than one semiconductor chip may be bonded to cooling element 15A.

FIG. 10 depicts a cross-sectional view of an example of cooling element 15B, in accordance with an embodiment of the present invention. In various embodiments, cooling element 15B is composed of silicon carbide. Cooling element 15B can be a silicon carbide plate or portion of a silicon carbide plate that has essentially the same size (e.g., the same width and length) as the semiconductor chip to which it is bonded. In some embodiments, cooling element 15B directly attaches to semiconductor chip 111 by bonding layer 11 instead of cooling element 15A depicted in FIG. 1. Similar to cooling element 15A, cooling element 15B can be attached to a semiconductor chip (e.g., semiconductor chip 111 depicted in FIG. 1) using bonding layer 11 (e.g., by a hybrid bonding process, thermal adhesive, etc.).

The thermal conductivity of silicon carbide, like copper, is greater than the thermal conductivity of silicon. Therefore, attaching cooling element 15B to the front side BEOL wiring on a semiconductor chip instead of the silicon carrier wafer increases the amount of heat that can be dissipated by the semiconductor chip.

In various embodiments, cooling element 15B is composed of silicon carbide. Silicon carbide can have a thermal conductivity in the range of 100 to 500 W/m deg. K but typically is in the range of 120 W/m deg. K for most semiconductor chip applications. The CTE of silicon carbide is approximately 4 ppm/C which is slightly larger than silicon. In some embodiments, cooling element 15B with a CTE closer to the thinned semiconductor substrate (e.g., silicon) would be a good candidate for attachment to the backside of the thinned semiconductor chip. For example, as depicted in FIG. 16, a conventional semiconductor chip without a BSPDN or backside BEOL wiring such as semiconductor chip 211 with a CTE closer to substrate 22 in semiconductor chip 211 would be a good candidate for attachment using a hybrid bond (e.g., an oxide hybrid bond) to semiconductor chip 211.

The thickness of cooling element 15B can be in the same range as the thickness of cooling element 15A but is not limited to this thickness. The thicknesses of cooling element 15B and cooling element 15A may be adjusted to meet the semiconductor chip thermal requirements (e.g., selected to dissipate enough heat for efficient semiconductor chip function). In an embodiment, cooling element 15B is composed of another material, such as aluminum that has a higher thermal conductivity than silicon.

FIG. 11 depicts a cross-sectional view of an example of a silicon microchannel structure for the cooling element 15C, in accordance with an embodiment of the present invention. As depicted, FIG. 11 includes semiconductor substrate 25A, semiconductor substrate 25B, microchannels 26, and bonding layer 21. Also, identified in FIG. 11 are W1, the width of a microchannel, W2, the width of a vertical semiconductor fin in semiconductor substrate 25B, and H, an example of the height of the inside portion of each of microchannels 26.

Thermal modeling of a silicon-based cooling element with microchannels 26 such as cooling element 15C predicted improved hot spot cooling (e.g., 7-10 degrees Celsius lower maximum hot spot temperature) with the silicon-based microchannel cooling element attached to BEOL wiring compared to a semiconductor device with the silicon carrier wafer attached to the BEOL wiring.

Cooling element 15C is composed of two semiconductor elements, semiconductor substrate 25A and semiconductor substrate 25B, that are joined together by bonding layer 21 to form microchannels 26 as depicted in FIG. 11. In various embodiments, semiconductor substrate 25A and semiconductor substrate 25B are composed of silicon. In other embodiments, a different semiconductor material (e.g., SiGe, Ge, sapphire, graphite, etc.) is used to form semiconductor substrate 25A and semiconductor substrate 25B. In various embodiments, microchannels 26 of cooling element 15C are filled with forced, chilled water. In other examples, other liquids may be used to fill and circulate through microchannels 26 in cooling element 15C.

Bonding layer 21 can be any material suitable for joining two semiconductor elements (e.g., semiconductor substrate 25A and 25B). For example, bonding layer 21 may be any of the materials suitable for hybrid bonding of semiconductor or silicon elements. Bonding layer 21 can be, but is not limited to, any of the bond layers discussed in FIG. 1 for bonding layer 11. More specifically, in some embodiments, a hybrid bonding process is used to bond the top surfaces of the fins in semiconductor substrate 25A to the top surfaces of the fins in semiconductor substrate 25B. In one case, the bonding process and the bonding layer 21 materials may be an oxide hybrid bonding process. In one embodiment, a very thin layer of a thermally conductive adhesive joins the fins of semiconductor substrate 25A to the fins of semiconductor substrate 25B. In another example, bonding layer 21 may be composed of one or more metals or metal alloys that can be fused together or melted together (e.g., using a eutectic bonding process, solder, or the like). In another example, a thermally conductive adhesive is used for bonding layer 21. Each of microchannels 26 is formed by fins bonded on the top surfaces by bonding layer 21. For example, as depicted in FIG. 11, four fins bonded by bonding layer 21 can form one of microchannels 26.

After semiconductor substrate 25A and 25B are bonded together as depicted in FIG. 11, microchannels 26 are formed. The width, W1, of microchannels 26 depicted in FIG. 11 is approximately 70 to 300 micrometers but microchannels 26 are not limited to these widths and W1 may be wider or narrower. As depicted in FIG. 11, the width, W1 of microchannels 26 is the same for semiconductor substrate 25A and semiconductor substrate 25B.

Semiconductor substrate 25A and 25B are each separately formed with vertical fins on the horizontal portion of each of semiconductor substrate 25A and 25B. The width, W2 of the vertical fins in semiconductor substrate 25B is approximately 60 to 150 micrometers but is not limited to this width. As depicted in FIG. 11, the width of the vertical fins in semiconductor substrate 25A is the same as the width, W2 of the vertical fins of semiconductor substrate 25B. For example, using known semiconductor processes, the vertical fins can be patterned and etched in a semiconductor wafer or a portion of a semiconductor wafer. For example, the fins in semiconductor substrates 25A and 25B can be formed in a semiconductor wafer with a wet etching process or a dry etching process such as reactive ion etch (RIE). The vertical height of microchannels 26 may vary depending on the height of the vertical fins in each of semiconductor substrate 25A and semiconductor substrate 25B. In one example, the vertical height, H, of microchannels 26 depicted in FIG. 11 may be 80 to 300 micrometers but is not limited to this height. In various examples of cooling clement 15C, the height, H. of microchannels 26, the width, W1, of microchannels 26, and the width, W2, of each of the fins in semiconductor substrate 25A and semiconductor substrate 25B can be varied to meet the desired thermal characteristics of the semiconductor chip that cooling element 15C is attached to.

In various embodiments, microchannels 26 are filled with chilled water that is forced through microchannels 26. The tooling and operational system to provide forced chilled water in microchannels 26 are known to one skilled in the art. Using cooling element 15C with water-filled microchannels 26 provides an improved ability of cooling element 15C to remove heat from a semiconductor chip that is attached to cooling element 15C. Cooling element 15C that is joined to front side BEOL wiring 30 of semiconductor chip 111 by bonding layer 11 instead of cooling element 15A depicted in FIG. 1 can increase the amount of heat transferred out of semiconductor chip 111 compared to a conventional silicon carrier wafer attached to semiconductor chip 111.

FIG. 12 depicts a cross-sectional view of an example of a copper microchannel structure for the cooling element 15D, in accordance with an embodiment of the present invention. As depicted, FIG. 12 includes copper element 33 with microchannels 36, bonding layer 31, and top copper plate 34. In some embodiments, cooling element 15D is composed of a different metal material (e.g., aluminum with an aluminum oxide surface). In various embodiments, cooling element 15D is directly attached to semiconductor chip 111 by bonding layer 11 (i.e., cooling element 15D replaces cooling element 15A in FIG. 1). In other embodiments, cooling element 15D can be directly bonded to the backside of a semiconductor chip substrate (e.g., to substrate 22 of semiconductor chip 221 of FIG. 16).

Cooling element 15D composed of copper with microchannels 36 that can be filled with chilled, circulating water can remove the thermal energy from the semiconductor chip more efficiently than the conventional silicon carrier wafer bonded to the front side BEOL wiring. Thermal modeling has predicted that hot spot cooling is significantly improved (e.g., 25-30 degrees Celsius lower maximum hot spot temperature) with a copper based microchannel cooling element such as cooling element 15C attached to BEOL wiring compared to a semiconductor device with the silicon carrier wafer attached to the BEOL wiring.

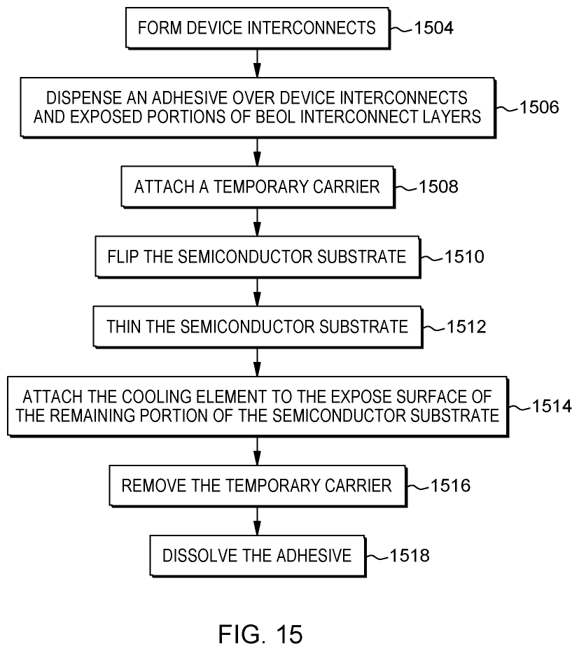

In various embodiments, cooling element 15D is composed of top copper plate 34 bonded by bonding layer 31 to copper element 33 with microchannels 36. In various embodiments, microchannels 36 of cooling clement 15D are filled with circulating or forced, chilled water. As previously discussed with respect to FIG. 15C, the method of providing forced chilled water through microchannels is known and, like cooling element 15C, the liquid is not limited to water. In various embodiments, the dimensions of microchannels 26 (i.e., W1, W2, and H) have essentially the same ranges as microchannels 26 in FIG. 11. However, in some examples, the dimensions for one or more of H, W1, and W2 can be larger than the range of dimensions discussed for microchannels 26. For example. microchannels 36 are smaller with lower value for one or more of H. W1, and/or W2 than microchannels 26. In the example of cooling element 15D depicted in FIG. 12, T2, the thickness of top copper plate 34 is in the range of 100 to 200 um.

Copper clement 33 can be formed, for example, from a thin copper plate that has been selectively etched using either a known wet copper etchant or a dry etching process such as a RIE to form microchannels 36. In another example, copper element 33 can be formed using known three-dimensional (3D) printing to form the fins on a copper base or to completely form copper element 33 with 3D printing. Top copper plate 34 can be joined to copper element 33, as depicted, by bonding layer 31. In some embodiments, bonding layer 31 is the same material as bonding layer 11 in FIG. 1. In other embodiments, bonding layer 31 is deposited and cured with a hybrid copper bonding process. In other embodiments, bonding layer 31 is a very thin layer of a thermally conductive adhesive. In some embodiments, bond layer 31 is a thin layer of a metal or metal alloy (e.g., solder) used to bond copper clement 33 to top copper plate 34 using known thermal processes such as heating for a metal reflow or a metal diffusion process.

In some embodiments, copper element 33 composed of microchannels 36 that can be filled with chilled water circulating through each of microchannels 36. When cooling element 15D is bonded to a semiconductor chip instead of bonding a conventional silicon carrier wafer, cooling element 15D provides much better thermal conductivity and a superior ability to remove more heat from the semiconductor chip. The dimensions of cooling element 15D and microchannels 36 can be varied depending on the semiconductor chip size, the desire amount of liquid and flow rate of the liquid in microchannels 36, and the amount thermal energy or heat to be released from the semiconductor chip. FIG. 12 provides one example of a cooling element 15D with microchannels 36, in other examples, the thickness of top copper plate 34 is different or a thickness of the horizontal bottom portion of copper element 33 may be different (e.g., thicker or thinner) than depicted in FIG. 12.

When attached to semiconductor chip 111 in FIG. 1, cooling element 15D composed of copper with forced, circulating, chilled water provides better thermal conductivity and an improved ability to remove more heat from semiconductor chip 111 in FIG. 1 than a conventional silicon carrier wafer attached to semiconductor chip 111. In some embodiments, cooling element 15D with chilled water flowing through microchannels 36 may be able to remove more heat from semiconductor chip 111 than cooling element 15A. One thermal hot spot thermal model of cooling element 15D with forced, chilled water in microchannels 26 removed enough thermal energy to have a maximum hot spot temperature that was 10-15 degrees Celsius less than cooling element 15C (i.e., a copper plate) with the same size attached to the same structure or semiconductor chip with the same cooling conditions (e.g., ambient temperature, air flow, etc.). Cooling element 15D attached to semiconductor chip 111 of FIG. 1 significantly increases the amount heat that can be removed from semiconductor structure 100 compared to semiconductor chip 111 attached to a conventional silicon carrier wafer. In some cases, cooling clement 15D may be joined to two or more semiconductor chips (e.g., bonded to either the front side BEOL interconnect wiring or to the backside of the semiconductor substrates). In another embodiment, cooling element 15D is directly bonded to semiconductor chip 211 instead of cooling element 15C depicted in FIG. 16. More than one semiconductor chip may be directly bonded to cooling element 15D. In one embodiment, two of semiconductor chip 111 are bonded by hybrid bonding to one of cooling element 15D.

In other embodiments, cooling element 15D is bonded by hybrid bonding to the backside of a thinned semiconductor substrate of a semiconductor chip (e.g., without backside BEOL wiring). For example, as depicted in FIG. 16, cooling element 15D is bonded by bonding layer 11 to substrate 22 of semiconductor chip 211. As depicted in FIG. 16 and discussed in step 1512 of FIG. 15, substrate 22 is thinned by a backside wafer grind process, for example.

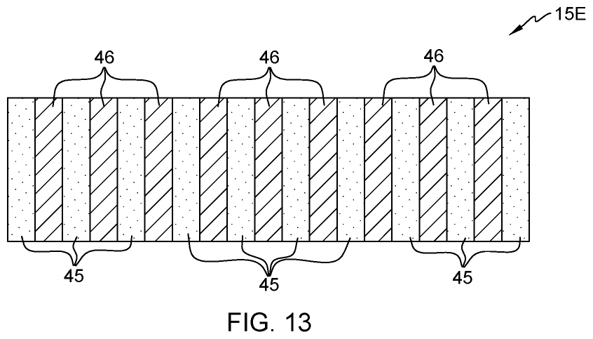

FIG. 13 depicts a cross-sectional view of an example of cooling element 15E composed of glass base 45 with copper-filled vias 46, in accordance with an embodiment of the present invention. As depicted, FIG. 13 includes glass base 45 with copper-filled vias 46. Cooling clement can have similar dimensions (e.g., length, width, and thickness) as cooling element 15A is not limited to those dimensions. Cooling element 15E can be bonded to either the backside of a semiconductor chip substrate (e.g., to substrate 22 of semiconductor chip 221 of FIG. 16) or the front side BEOL interconnect wiring of a semiconductor chip (e.g., to substrate 2 of semiconductor chip 111 of FIG. 1).

Glass base 45 can be a glass plate formed, for example, using known glass melting and formation processes and, then glass base 45. Using known methods, glass base 45 can be made with a CTE approximately matching the CTE of the semiconductor substrate of semiconductor chip. As known in the art, manipulation of the components or elements comprising glass base 45 of cooling element 15E can provide some changes in the CTE of conventional glass to more closely match the CTE of the BEOL wiring. For example, CTE of glass may range from 3.5 to 9 ppm/C and the CTE of BEOL wiring may be in the range of 9 to 13 ppm/C. In this way, the material of glass base 45 can be selected to minimize CTE mismatch with either BEOL wiring for attachment to semiconductor chip 111 of FIG. 1 or substrate 22 in semiconductor chip 221 of FIG. 16. Glass base 45 may have a rectangular or square flat or plate-like shape. Glass base 45 may a thickness in the range of 200 to 800 um but is not limited these thicknesses. Glass base 45 can have a length and width matching the size of the semiconductor chip to which it is bonded. Glass typically has a thermal conductivity in the 0.8 to 1 W/m deg. K but some glass materials (e.g., with MgO) have a higher thermal conductivity. The thermal conductivity of the copper in the copper-filled vias of cooling element 15E is much higher (e.g., 365 W/m deg. K).

In various embodiments, copper-filled vias 46 are formed in glass base 45 as depicted in FIG. 13. The vias for copper-filled vias 46 can be formed using known semiconductor processes (e.g., lithography, via hole etch can occur using a reactive ion etching (RIE) process or a wet chemical etching process). The via fill can occur using one or more of electroplating, atomic layer deposition, chemical vapor deposition, electroless plating, or the like.

In some embodiments, the diameter of copper-filled vias 46, the location, and the number of copper-filled vias 46 may be determined for each semiconductor chip. For example, copper-filled vias 46 may be 10 to 200 um in diameter but are not limited to theses diameters. The location, size, and number of vias may be determined using a thermal analysis of the semiconductor chip and the environment it will operate in. The size, location, and number of copper-filled vias 46 may be determined by thermal modelling to optimize the thermal performance of the semiconductor chip.

In various embodiments, cooling element 15E can be attached to a thinned semiconductor substrate with the backside BEOL wiring or attached to a semiconductor substrate without backside BEOL wiring. Using a thinned semiconductor substrate such as substrate 22 in FIG. 16 can shorten the thermal path for the cooling of semiconductor chip 211 through substrate 22. Substrate 22 (e.g., silicon or another semiconductor material) has a low thermal conductivity. In some embodiments, cooling element 15E is joined by hybrid bonding to a thinned semiconductor. Cooling element 15E can be attached to a semiconductor substrate using any of the suitable hybrid bonding processes, a wafer-to-wafer bonding process modified for glass-to-wafer bonding, a thermally conductive adhesive, or another thermal interface material suitable for glass and copper via attachment to a semiconductor substrate. In another embodiment, cooling element 15D is attached to a BEOL wiring layer. For example, cooling element 15E may be attached using bonding layer 11 (e.g., using an oxide bonding process) to semiconductor chip 111 instead of cooling element 15A depicted in FIG. 1.

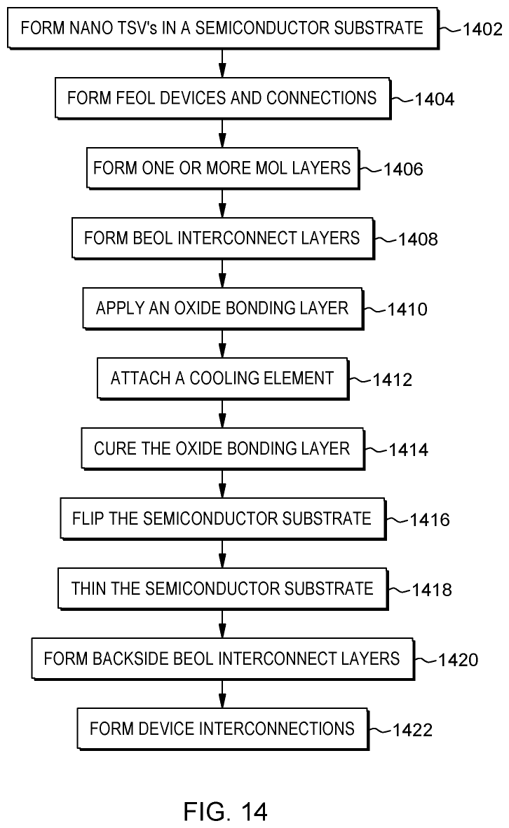

FIG. 14 is a flow chart 1400 depicting an example of the operational steps to form a semiconductor chip 111 with a cooling element, in accordance with an embodiment of the present invention. The operational steps to form semiconductor structure 100 depicted in FIG. 1 include forming TSVs or nano TSVs in the semiconductor substrate in step 1402. In some embodiments, the TSVs (e.g., TSVs 3 depicted in FIG. 1) can be etched as blind vias. In some examples, the blind TSVs may be etched for nano TSVs. In other examples, the TSVs can be etched through the semiconductor substrate. The TSVs may be nano TSVs or conventional TSVs that are lined and filled using known TSV processes and materials.

In step 1404, the FEOL devices (e.g., finFETs, GAA nanosheet FET devices, etc.) are formed in a first metal layer (e.g., M0 metal) on the semiconductor substrate using known semiconductor processes. In some examples, the TSVs may contact a FEOL device.

Forming one or more MOL layers occurs in step 1406. As known to one skilled in the art, the MOL layers may include a number of contacts to the FEOL devices, some additional MOL devices (e.g., memory devices, etc.), and one or more dielectric material layers. BEOL interconnect layers may be formed in step 1408 using known BEOL processes. Several or many layers of BEOL wiring and connections may be formed in several layers of dielectric material (e.g., ILD).

In step 1410, the bond layer (e.g., bonding layer 11 in FIG. 1) is applied. For example, using a spin coating process, CVD, or other similar bonding layer deposition process to apply a thin coat of an oxide-based material for hybrid bonding. In one embodiment, a very thin layer of oxide is deposited by atomic layer deposition or chemical vapor deposition. In some cases, when the cooling element is composed of a copper material, the materials for a hybrid copper bond can be applied to the surface of the front side BEOL wiring. In other cases, a layer of a polymer material is applied.

In step 1412, attach cooling element (e.g., cooling element 15A), using known carrier wafer or chip placement tools to the semiconductor chip. In other examples, one of cooling element 15B, cooling element 15C, cooling element 15D or cooling element 15E are aligned and attached to the semiconductor chip. The cooling element is aligned with the semiconductor substrate and placed on the bonding layer over the front side BEOL interconnect layers. In step 1414, the bond layer is cured, for example, using known hybrid bonding processes or the manufacturer provided specifications in the case of a polymer material or a thermally conductive adhesive for the bonding layer. In other examples, the bonding layer may be a metal or a metal alloy (e.g., very thin layer of solder) that may be joined by an elevated temperature. The cooling element is directly bonded to the front side BEOL interconnect layers by the bonding layer.

In step 1416, flip the semiconductor substrate so that the bottom surface of the semiconductor substrate is exposed as the top surface of the semiconductor structure. In step 1418, thin the semiconductor substrate by using known backside wafer grinding processes and/or a wet chemical etch. After thinning the semiconductor substrate, surfaces of the TSVs are exposed and the thinned semiconductor substrate has a thickness in the range of 5 to 10 um.

In step 1420, form the backside BEOL interconnect layers using known BEOL semiconductor processes. The backside BEOL interconnect layers connect to the FEOL devices by the TSVs or nano TSVs. In some embodiments, a backside power delivery network is formed by the backside BEOL interconnect layers.

In step 1422, the device interconnections are formed. The device interconnections can be any type of interconnections used to attach the semiconductor chip to another chip or to a next packaging level such as a laminate, ceramic, flex, or other module substrate. The device interconnections may be solder balls, solder bumps, copper pillars, etc. but are not limited to these types of device connections.

FIG. 15 is a flow chart depicting an example of the operational steps to attach a cooling element to a backside of a semiconductor chip, in accordance with an embodiment of the present invention. The operational steps of FIG. 15 create a semiconductor chip with a thinned semiconductor substrate without backside BEOL wiring that is attached to a cooling element. For example, in one embodiment depicted in FIG. 16, semiconductor chip 211 is bonded to cooling element 15C (e.g., a silicon-based cooling element with water-filled microchannels). In other embodiments, the operational steps of FIG. 15 attach any cooling element of cooling elements 15A, 15B, 15C. 15D, or 15E to the backside of the semiconductor chip formed with the operational steps of FIG. 15. The operational steps of FIG. 15 start with a conventional semiconductor chip with FEOL devices on the semiconductor substrate, MOL layers above the FEOL devices, BEOL interconnect layers over the MOL layers, and device interconnects (e.g., solder bumps) on BEOL interconnect layers.

In step 1506, dispense an adhesive over the device interconnects and the exposed portions of the BEOL interconnect layers. The adhesive is a dissolvable adhesive that is capable of withstanding BEOL semiconductor processes. The adhesive is thicker than the height of the device interconnects. In step 1508, attach a temporary carrier to the adhesive. The temporary carrier can be a carrier wafer, a metal plate, or other type of temporary carrier. The temporary carrier on the adhesive is above and over the device interconnects. The device interconnects are above the BEOL interconnect wiring.

In step 1510, flip the semiconductor substrate to expose the backside of the semiconductor substrate. In step 1512, thin the semiconductor substrate. Using known backside wafer grinding processes that may be combined with a semiconductor etching processes (e.g., a wet etch process) to remove the backside of the semiconductor substrate.

In step 1514, attach the cooling element (e.g., cooling element 15C depicted in FIG. 16) to the exposed surface of the remaining portion of the thinned semiconductor substrate. For example, using the bond layer, such as bond layer 11, deposited on the top surface of the thinned semiconductor substrate after thinning the semiconductor substrate for example by spin coating or chemical vapor deposition, the cooling element is directly attached to the backside of the thinned semiconductor substrate. After curing the bond layer, the cooling element is attached the backside of the thinned semiconductor substrate. The cooling element can be one of cooling clement 15A, 15B, 15D, or 15E that is attached to the backside of the thinned semiconductor substrate. In some embodiments, one of cooling elements 15B, 15C, or 15E are selected for attachment to the thinned semiconductor substrate due a CTE that is similar to or approximately matching the CTE of the thinned semiconductor substrate. For example, a thinned silicon substrate with a CTE in the range of 2.6 ppm/C could be closely or approximately matched by of cooling elements !5B (silicon carbide), cooling element 15C (silicon substrate with microchannels), and cooling element 15E (glass plate with copper-filled vias). In some embodiments, more than one semiconductor chip is bonded to the cooling element.

In step 1516, remove the temporary carrier. For example, the temporary carrier may be peeled away from the adhesive. In one example, a heating element or hot air may help release the temporary carrier. In step 1518, dissolve the adhesive on device interconnects and the surface of the BEOL interconnect layers. In some embodiments, steps 1516 and 1518 can be reversed and the adhesive may be dissolved and, then the temporary carrier is removed. In one example, after removing the temporary carrier, the semiconductor structure formed is semiconductor structure 1600 depicted in FIG. 16. In other examples, a different cooling element such as cooling clement 15B or 15E is attached to the backside of the thinned semiconductor substrate. Cooling elements 15B, 15C, and 15E have the CTEs most closely matching the CTE of silicon substrate 22 depicted in FIG. 16. In another example, cooling element 15A or 15D is attached to substrate 22.

FIG. 16 depicts a cross-sectional view of semiconductor structure 1600 with the backside of substrate 22 in semiconductor chip 211 joined to cooling element 15C, in accordance with an embodiment of the present invention. As depicted, FIG. 16 includes cooling element 15C, bonding layer 11, semiconductor chip 211 with substrate 22, FEOL devices 10, MOL layers 20, BEOL wiring 30, and interconnects 16. FEOL devices 10, MOL layers 20, BEOL wiring 30, bonding layer 11, and interconnects 16 are essentially the same described in detail with respect to FIG. 1. Semiconductor chip 211 does not include backside BEOL wiring. Substrate 22 is thinned similar to substrate 2 depicted in FIG. 1 but does not include TSVs 3. In other embodiments, substrate 22 is directly joined to one of cooling element 15A, cooling element 15B, cooling element 15D, or cooling element 15E. The hybrid bond directly attaching cooling element 15C is between the surface of the backside of substrate 22 and cooling element 15C. In one example, two or more of substrate 22 are joined to one of cooling elements 15A-15E using hybrid bonding.

In various embodiments, cooling element 15C formed from semiconductor substrates 25A and 25B with water-filled microchannels 26 (depicted in FIG. 11) is attached by bonding layer 11 to the backside of semiconductor chip 221. Cooling element 15C provides a CTE essentially the same as substrate 22 and with forced, water-filled microchannels 26 provides a higher thermal conductivity than the silicon of substrate 22 to remove heat from semiconductor chip 211. In other embodiments, cooling element 15E is joined to semiconductor chip 211 in the place of cooling element 15C. Cooling element 15E also provides a similar CTE as substrate 22 and an improved thermal conductivity due to copper-filled vias 46. In some cases, cooling clement 15A or 15D are attached by bond layer 11 to substrate 22.

While the invention has been shown and described with reference to certain exemplary embodiments thereof, it will be understood by those skilled in the art that various changes in form and details may be made therein without departing from the spirit and scope of the present invention as defined by the appended claims and their equivalents. The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a semiconductor chip with a front side back-end-of-line (BEOL) interconnect wiring; and
a cooling element directly bonded to the front side BEOL interconnect wiring.

2. The semiconductor structure of claim 1, wherein the cooling element directly bonded to the front side BEOL interconnect wiring is a hybrid bond.

3. The semiconductor structure of claim 1, wherein the cooling element is selected from the group consisting of a metal-based cooling element, a semiconductor material-based cooling element, and a glass material-based cooling element with copper-filled vias.

4. The semiconductor structure of claim 2, wherein the hybrid bond is selected from the group consisting of a copper hybrid bond, an oxide hybrid bond, and an oxide-copper hybrid bond.

5. The semiconductor structure of claim 1, wherein the semiconductor chip includes a backside BEOL interconnect wiring under (i) a thinned semiconductor substrate and (ii) one or more through-silicon vias.

6. A semiconductor structure comprising:
a semiconductor chip with a front side back-end-of-line (BEOL) interconnect wiring, a backside BEOL interconnect wiring, and one or more through-silicon vias; and
a copper cooling element with a plurality of microchannels directly bonded to the front side BEOL interconnect wiring.

7. The semiconductor structure of claim 6, wherein the copper cooling element with the plurality of microchannels includes chilled, circulating water in the plurality of microchannels.

8. The semiconductor structure of claim 6, wherein the copper cooling element with the plurality of microchannels has a similar thermal co-efficient of expansion as the backside BEOL interconnect wiring.

9. The semiconductor structure of claim 8, wherein the copper cooling element with the plurality of water-filled microchannels includes circulating chilled water in the plurality of water-filled microchannels.

10. The semiconductor structure of claim 6, wherein the copper cooling element directly bonded to the front side BEOL interconnect wiring uses a direct bond selected from the group consisting of a copper hybrid bond, an oxide hybrid bond, and an oxide-copper hybrid bond.

11. A semiconductor structure comprising:
a semiconductor chip with a semiconductor substrate; and
a semiconductor cooling element directly bonded to the semiconductor substrate.

12. The semiconductor structure of claim 11, wherein the semiconductor substrate is a thinned semiconductor substrate.

13. The semiconductor structure of claim 11, wherein the semiconductor cooling element is a silicon cooling element with a plurality of microchannels filled with circulating chilled water.

14. The semiconductor structure of claim 11, wherein the semiconductor cooling element is a silicon carbide plate.

15. The semiconductor structure of claim 11, wherein the semiconductor cooling element is directly bonded to the semiconductor substrate by a hybrid bond.

16. The semiconductor structure of claim 15, wherein the hybrid bond is an oxide hybrid bond.

17. A semiconductor structure comprising:
a semiconductor chip with a thinned semiconductor substrate; and
a copper plate cooling element directly bonded to a backside of the thinned semiconductor substrate.

18. The semiconductor structure of claim 17, wherein the copper plate cooling element has a similar thermal co-efficient of expansion as the backside BEOL interconnect wiring.

19. The semiconductor structure of claim 17, wherein the copper plate cooling element directly bonded to the backside of the thinned semiconductor substrate is directly bonded to the backside of the thinned semiconductor substrate by a hybrid bond.

20. The semiconductor structure of claim 17, wherein the copper plate cooling element directly bonded to the backside of the thinned semiconductor substrate includes a copper hybrid bond between the metal cooling element and the backside of the thinned semiconductor substrate.

21. The semiconductor structure of claim 17, wherein the copper plate cooling element directly bonded to a backside of the thinned semiconductor substrate includes an oxide hybrid bond between the metal cooling element and the backside of the thinned semiconductor substrate.

22. The semiconductor structure of claim 17, wherein the copper plate cooling element directly bonded to a backside of the thinned semiconductor substrate includes a polymer material between the metal cooling element and the backside of the thinned semiconductor substrate.

23. A method of forming a semiconductor structure comprising:
forming one or more through-silicon-vias in a semiconductor substrate;
forming a plurality of front-end-of-line semiconductor devices;
forming one or more middle-of-line layers on the plurality of front-end-of-line semiconductor devices;
forming back-end-of-line (BEOL) interconnect wiring;
depositing a bonding layer on the back-end-of-line (BEOL) interconnect wiring, wherein the bonding layer is a material for hybrid bonding;
attaching a cooling element to the BEOL interconnect wiring;
curing the bonding layer using a hybrid bonding process;
flipping the semiconductor substrate;
backside grinding the semiconductor substrate to thin the semiconductor substrate;
forming a backside BEOL interconnect wiring, and wherein the backside BEOL interconnect wiring is a backside power delivery network; and
forming a plurality of interconnects on the backside BEOL interconnect wiring.

24. The method of claim 23, wherein the cooling element is selected from the group consisting of a silicon cooling element with water-filled microchannels, a glass cooling element with copper-filled vias, a silicon carbide cooling plate, a copper plate cooling element, and a copper cooling element with the water-filled microchannels.

25. The method of claim 23, wherein the material for the hybrid bonding is selected from the group consisting of an oxide material, a copper material, and a combination of the oxide material and the copper material.
